(19) United States
(12) Patent Application Publication
(10) Pub. No.: US 2008/0123391 A1
(43) Pub. Date: May 29, 2008

(54) Memory system and resistive memory device including buffer memory for reduced overhead

(76) Inventors: Woo-Yeong Cho, Suwon-si (KR); Du-Eung Kim, Yongin-si (KR); Kwang-Jin Lee, Hwaseong-si (KR)

Correspondence Address: LAW OFFICE OF MONICA H CHOI, P O BOX 3424, DUBLIN, OH, 430160204, US

(21) Appl. No.: 11/901,438

(22) Filed: Sep. 17, 2007

(30) Foreign Application Priority Data
Nov. 2, 2006 (KR) 2006-107945

(51) Int. Cl. G11C 11/00; G11C 7/00; G11C 8/00

(52) U.S. Cl. 365/148; 365/189.05; 365/230.06

(57) ABSTRACT

A resistive memory device includes a memory core unit and a buffer memory for reducing overhead of a memory controller in a memory system. The buffer memory stores input data associated with a write command. The memory core unit includes resistive memory cells for storing the input data from the buffer memory. The buffer memory is comprised of a different type of memory cells from the resistive memory cells such that the different type of memory cells writes the input data with a faster speed than the resistive memory cells.

### BACKGROUND OF THE INVENTION

This application claims priority under 35 USC § 119 to Korean Patent Application No. 2006-107945, filed on Nov. 2, 2006 in the Korean Intellectual Property Office, the disclosure of which is incorporated herein in its entirety by reference.

1. Field of the Invention

The present invention relates generally to resistive memory devices, and more particularly, to a resistive memory device including a buffer memory used to store input data for reduced overhead of a memory controller in a memory system.

2. Background of the Invention

A random access memory (RAM) device is used to store data in an electronic system such as a computer system, communication equipment, and the like. Memory cells of a phase-change RAM (PRAM) device include phase-change material set to one of two physical states for storing data. For example, a first physical state is a high resistance state for expressing a binary “1”, and a second physical state is a low resistance state for expressing a binary “0”.

When a PRAM device including a memory cell array of phase-change memory cells is included in an electronic system, even if power is not supplied to the PRAM device, the data stored in the memory cells of the PRAM device is not lost given the characteristics of the phase-change material. Thus, a PRAM device is a non-volatile memory device in contrast to a dynamic random access memory (DRAM) device.

FIG. 1 is a block diagram of a conventional memory system 10. Referring to FIG. 1, the memory system 10 includes a memory controller 20 and a PRAM (phase-change random access memory) device 30. The memory controller 20 transmits an address signal ADD and a command signal CMD that control data DQ to be input/output into/from the PRAM device 30. The data DQ includes input data and output data.

Generally, since the PRAM device 30 stores data using a phase-change material such as GST (Ge₂—Sb₂—Te₅), the PRAM device 30 may write the data DQ slower than a static random access memory (SRAM) device or a DRAM device. Also, the PRAM device 30 may write the data DQ slower than the PRAM device 30 reads the data DQ.

When the memory controller 20 controls a data write operation of the PRAM device 30 that writes the data DQ relatively slowly, the memory controller 20 cannot perform another separate operation during the data write operation. In particular, when the data write operation is a burst write operation that successively writes a large amount of data such as for a page unit, the overhead of the memory controller 20 may increase.

Therefore, a PRAM device capable of reducing the overhead of the memory controller 20 is desired. The overhead of the memory controller 20 may also increase for a resistive random access memory (RRAM) device including resistive memory cells having a similar function to phase-change memory cells.

### SUMMARY OF THE INVENTION

Accordingly, a resistive memory device of the present invention includes a buffer memory for reducing overhead of a memory controller in a memory system.

A resistive memory device according to an embodiment of the present invention includes a buffer memory and a memory core unit. The buffer memory stores input data associated with a write command. The memory core unit includes resistive memory cells for storing the input data from the buffer memory. The buffer memory is comprised of a different type of memory cells from the resistive memory cells such that the different type of memory cells writes the input data with a faster speed than the resistive memory cells.

In another embodiment of the present invention, the resistive memory device further includes a first control logic unit that generates a write address signal and a write command signal to the buffer memory in response to the write command and an address from a memory controller. The buffer memory stores the input data in response to the write command signal and the write address signal.

In a further embodiment of the present invention, the buffer memory generates a buffer status signal to the first control logic unit for indicating when the input data is completely stored in the memory core unit.

In another embodiment of the present invention, the memory core unit is controlled to perform another command from the memory controller before the input data is completely stored in the memory core unit.

In a further embodiment of the present invention, the resistive memory device includes an output buffer that receives output data from the memory core unit for a read command. In addition, the buffer memory also stores the output data from the memory core unit for the read command. In that case, the output buffer transmits the output data from one of the buffer memory and the memory core unit according to a selection signal from the first control logic unit.

In another embodiment of the present invention, the memory core unit includes a memory cell array of the resistive memory cells, a second control logic unit, a write driver, a sense amplifier, and an address decoder. The second control logic unit generates a control signal for controlling writing of the input data into the memory cell array and reading of the output data from the memory cell array according to the write address signal, the write command signal, a read address signal, and a read command signal that are generated by the first control logic unit. The write driver writes the input data into the memory cell array in response to the control signal. The sense amplifier senses the output data from the memory cell array in response to the control signal. The address decoder generates a decoded write address signal indicating an area of the memory cell array to be storing the input data and a decoded read address signal indicating an area of the memory cell array having the output data that is read.

In a further embodiment of the present invention, the resistive memory cells are one of PRAM (phase-change random access memory) cells or RRAM (resistive random access memory) cells. In that case, the different type of memory cells of the buffer memory is one of SRAM (static random access memory) cells or DRAM (dynamic random access memory) cells.

The resistive memory device with such a buffer memory of the present invention is advantageous for reducing overhead for a memory controller in a memory system having the resistive memory device.

### BRIEF DESCRIPTION OF THE DRAWINGS

The above and other features and advantages of the present invention will become more apparent when described in detailed exemplary embodiments thereof with reference to the attached drawings in which:

FIG. 1 is a block diagram of a conventional memory system;

FIG. 2 is a block diagram of a memory system according to an embodiment of the present invention;

FIG. 3 is a detailed block diagram of a memory core unit of FIG. 2, according to an embodiment of the present invention; and

FIG. 4 shows a flow-chart of steps during operation of the memory system of FIG. 2, according to an embodiment of the present invention.

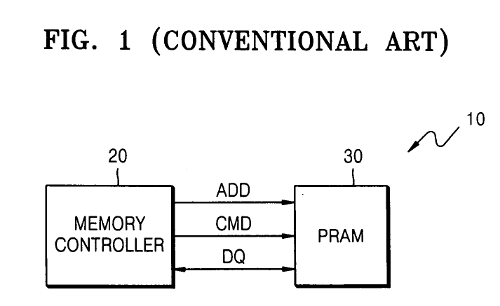

The figures referred to herein are drawn for clarity of illustration and are not necessarily drawn to scale. Elements having the same reference number in FIGS. 1, 2, 3, and 4 refer to elements having similar structure and/or function.

### DETAILED DESCRIPTION OF THE INVENTION

The present invention will now be described more fully with reference to the accompanying drawings, in which embodiments of the invention are shown. The invention may, however, be embodied in many different forms and should not be construed as being limited to the embodiments set forth herein. Rather, these embodiments are provided so that this disclosure will be thorough and complete, and will fully convey the concept of the invention to those skilled in the art.

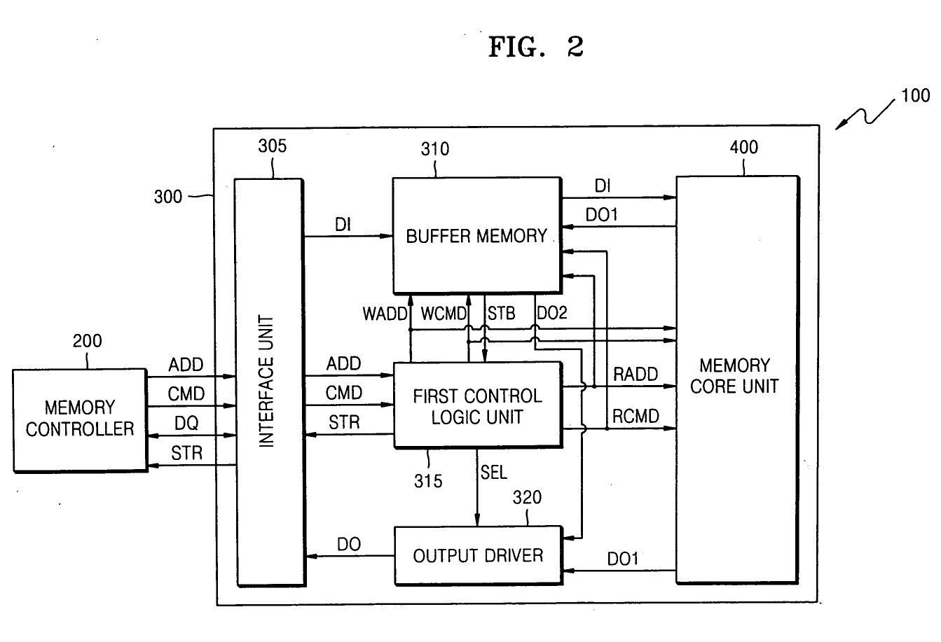

FIG. 2 is a block diagram of a memory system 100 according to an embodiment of the present invention. Referring to FIG. 2, the memory system 100 includes a memory controller 200 and a resistive memory device 300. The resistive memory device 300, for example, is a phase-change random access memory (PRAM) device or a resistive random access memory (RRAM) device, according to an example embodiment of the present invention.

The memory controller 200 transmits a command CMD and an address ADD associated with such a command to the resistive memory device 300. The address ADD specifies an address of the resistive memory device 300 that is controlled to input/output data DQ associated with the command CMD. The data DQ includes input data (or write data) DI to be written to the address ADD of the resistive memory device 300 and output data (or read data) DO to be read from the address ADD of the resistive memory device 300.

The memory controller 200 receives a resistive memory status signal STR from the resistive memory device 300 indicating an operation status of the resistive memory device 300. For example, the resistive memory status signal STR indicates when the input data DI from a buffer memory 310 is completely stored in a memory core unit 400 within the resistive memory device 300.

The resistive memory device 300 includes an interface unit 305, the buffer memory 310, a first control logic unit 315, an output driver 320, and the memory core unit 400. The interface unit 305 is for signal transition requirements such as input/output voltage level compatibility between the memory controller 200 and the resistive memory device 300. The first control logic unit 315 generates a write address signal WADD and a write command signal WCMD in response to the address ADD and the command CMD that is for a write operation as transmitted from the memory controller 200 via the interface unit 305.

When the memory controller 200 issues such a command CMD that is for writing of input data DI to the memory core unit 400, the write command signal WCMD is generated to control the buffer memory 310 to store the input data DI. Such input data DI is temporarily stored in the buffer memory 310 for eventually being written into the resistive memory cells of the memory core unit 400. The write address signal WADD designates the area of the buffer memory 310 for storing the input data DI and of the resistive memory cells in the memory core unit 400 for eventually storing such input data DI.

The first control logic unit 315 also generates a read address signal RADD, a read command signal RCMD, and an output data selection signal SEL in response to the address ADD and the command CMD that is for a read operation as transmitted from the memory controller 200 via the interface unit 305. When the memory controller 200 issues such a command CMD that is for reading of output data DO from the memory core unit 400, the read command signal RCMD is generated to control the memory core unit 400 to output first output data DO1 to the buffer memory 310 and to the output driver 320. In addition, the read command signal RCMD is generated to control the first output data DO1 that is stored in the buffer memory 310 to be output to the output driver 320 as second output data DO2. The read address signal RADD designates the area of the resistive memory cells of the memory core unit 400 storing the first output data DO1. In addition, the read address signal RADD also designates the area of the buffer memory 310 storing the first output data DO1.

The first control logic unit 315 generates the resistive memory status signal STR transmitted to the memory controller 200 via the interface unit 305. The resistive memory status signal STR includes a buffer status signal STB indicating an operation status of the buffer memory 310.

The memory core unit 400 of the resistive memory device 300 is formed of an array of resistive memory cells such as phase-change random access memory (PRAM) cells or resistive random access memory (RRAM) cells for storing the input data DI or output data DO. The buffer memory 310 is formed of an array of a different type of memory cells from the resistive memory cells of the memory core unit 400.

For example, the buffer memory 310 is comprised of an array of SRAM (static random access memory) cells or of DRAM (dynamic random access memory) cells for storing the input data DI or output data DO1. Such different type of memory cells of the buffer memory 301 writes the input data DI or output data DO1 with faster speed than the resistive memory cells of the memory core unit 400.

In addition, the buffer memory 310 also reads output data DO1 stored therein with a relative fast speed. For example, the write speed of the buffer memory 310 may be substantially same as the read speed of the buffer memory 310. Thus, the buffer memory 310 may successively write/read a plurality of pieces of data such as by a page unit with fast speed.

The buffer memory 310 temporarily stores the input data DI transmitted from the memory controller 200 via the interface unit 305 in response to the write address signal WADD and the write command signal WCMD. The buffer memory 310 outputs the buffer status signal STB indicating the operation status of the buffer memory 310 to the first control logic unit 315. The buffer status signal STB indicates when the input data DI as temporarily stored in the buffer memory 310 is completely stored into the resistive memory cells of the memory core unit 400.

The buffer memory 310 also temporarily stores the first output data DO1 read from the resistive memory cells of the memory core unit 400. The first output data DO1 is output as the second output data DO2 to the output driver 320 in response to the read address signal RADD and the read command signal RCMD.

The memory core unit 400 writes the input data DI provided by the buffer memory 310 into the resistive memory cells of the memory core unit 400 in response to the write address signal WADD and the write command signal WCMD from the first control logic unit 315. The memory core unit 400 also outputs the output data DO1 stored in the resistive memory cells of the memory core unit 400 to the buffer memory 310 and the output driver 320 in response to the read address signal RADD and the read command signal RCMD from the first control logic unit 315.

The output driver 320 selects one of the first output data DO1 from the memory core unit 400 or the second output data DO2 from the buffer memory 310 for transmission to the memory controller 200 via the interface unit 305 as the final output data DO in response to the output data selection signal SEL from the first core logic unit 315. The output data selection signal SEL may be included in the read command signal RCMD.

When the memory controller 200 requires the output data DO immediately, the output driver 320 is controlled by the output data selection signal SEL (that is set to a low level for example) to select the first output data DO1 from the memory core unit 400 as the final output data DO. Alternatively, when the memory controller 200 does not require the output data DO immediately (for example, when the memory controller 200 performs an independent operation other than the data read operation), the output driver 320 is controlled by the output data selection signal SEL (that is set to a high level for example) to select the second output data DO2 temporarily stored in the buffer memory 310 as the final output data DO.

The buffer memory 310 of the resistive memory device 300 is used for temporarily storing a high amount of input data DI temporarily before such data is eventually written into the resistive memory cells of the memory core unit 400. Therefore, the memory controller 200 of the memory system 100 may perform an independent operation other than performing the write operation while such input data DI is being written into the resistive memory cells of the memory core unit 400 with slower speed. Thus, such use of the buffer memory 310 advantageously reduces the overhead of the memory controller 200.

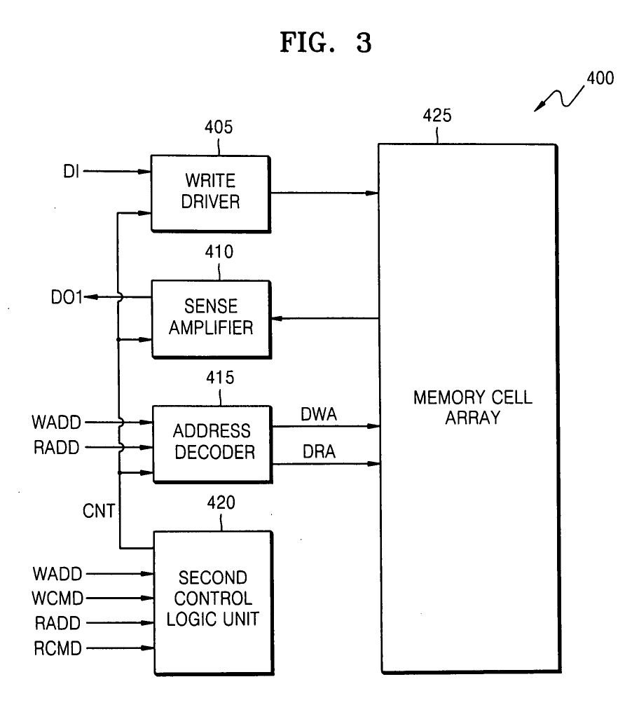

FIG. 3 is a detailed block diagram of the memory core unit 400 of FIG. 2, according to an embodiment of the present invention. Referring to FIG. 3, the memory core unit 400 includes a write driver 405, a sense amplifier 410, an address decoder 415, a second control logic unit 420, and a memory cell array 425. The memory cell array 425 is the array of the resistive memory cells for the memory core unit 400.

The second control logic unit 420 generates a control signal CNT including an enable signal for activating the write driver 405, the sense amplifier 410, and the address decoder 415. The control signal CNT is generated by the second control logic unit 420 in response to a combination of the write address signal WADD, the write command signal WCMD, the read address signal RADD, and the read command signal RCMD from the first control logic unit 315.

The address decoder 415 decodes the write address signal WADD from the first control logic unit 315 to generate a decoded write address signal DWA in response to the control signal CNT. The decoded write address signal DWA designates an area of the resistive memory cells of the memory cell array 425 for storing the input data DI. The address decoder 415 also decodes the read address signal RADD from the first control logic unit 315 to generate a decoded read address signal DRA in response to the control signal CNT. The decoded read address signal DRA designates an area of the resistive memory cells of the memory cell array 425 that has the first output data DO1 stored therein.

The write driver 405 writes the input data DI from the buffer memory 310 into the area of the resistive memory cells of the memory cell array 425 as indicated by the decoded write address signal DWA in response to the control signal CNT. The sense amplifier 410 senses data as stored in the area of the resistive memory cells of the memory cell array 425 as indicated by the decoded read address signal DRA, amplifies such sensed data, and outputs such amplified data as the first output data DO1 in response to the control signal CNT.

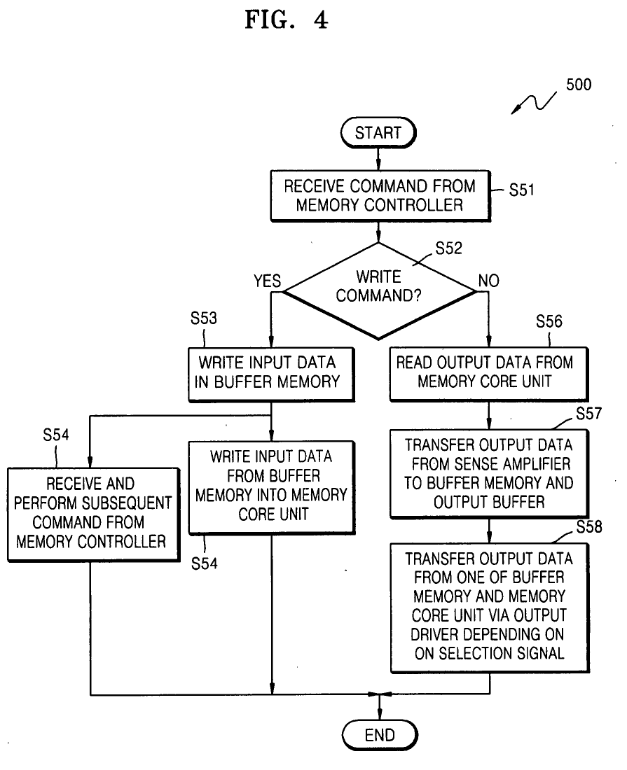

FIG. 4 shows a flow-chart 500 of method steps during operation of the memory system 100 according to an embodiment of the present invention. The first control logic unit 315 first receives a command CMD and an associated address ADD from the memory controller 200 via the interface unit 305 (step S51 in FIG. 4). Subsequently, the first control logic unit 315 determines whether such a command CMD is for a write operation (i.e., a write command) or a read operation (i.e., a read command) (step S52 in FIG. 4).

If the command CMD is for a write operation, the first control logic unit 315 generates the write command signal WCMD and the write address signal WADD to the buffer memory 310. The input data DI associated with such a write command is transmitted to the buffer memory 310 via the interface unit 305. The buffer memory 310 stores such input data DI at the address indicated by the write address signal WADD in response to the write command signal WCMD (step S53 of FIG. 4).

Subsequently, the memory core unit 400 writes such input data DI as stored in the buffer memory 310 at areas of the resistive memory cells of the memory cell array 425 as indicated by the write address signal WADD in response to the write command signal WCMD (step S54 of FIG. 4). The speed of the memory core unit 400 writing such input data DI is slower than the speed of the buffer memory 310 having written such input data DI.

Thus, as the memory core unit 400 writes the input data DI as stored into the buffer memory 305, the resistive memory device 300 may receive and perform a subsequent independent command from the memory controller 200 (step S55 o FIG. 4). For example, the memory controller 200 may write additional input data DI into or read output data DO from areas of the memory cell array 425 not writing the original input data DI from the buffer memory 310. Thus, the overhead of the memory controller 200 is minimized.

Back in step S52 of FIG. 4, if the original command CMD from the memory controller 200 is for a read operation, the first control logic unit 315 generates the read command signal RCMD and the read address signal RADD to the memory core unit 400 in response to such a command CMD and associated address ADD from the memory controller 200. The memory core unit 400 generates the output data DO1 in response to the read command signal RCMD and the read address signal RADD (step S56 in FIG. 4).

The first output data DO1 is transferred from the sense amplifier 410 of the memory core unit 400 to the buffer memory 310 and the output driver 320 (step S57 of FIG. 4). The buffer memory 310 temporarily stores such first output data DO1. In addition, the output driver 320 is controlled by the output data selection signal SEL to select one of the output data DO2 from the buffer memory 310 or the output data DO1 from the memory core unit 400 as the final output data DO transmitted to the interface unit 305 (step S58 of FIG. 4).

In this manner, the buffer memory 310 is used to temporarily store data DI or DO1 with a fast writing speed for reducing the overhead of the memory controller 200. While the present invention has been particularly shown and described with reference to an exemplary embodiment thereof, it will be understood by those of ordinary skill in the art that various changes in form and details may be made therein without departing from the spirit and scope of the present invention as defined by the following claims.

The present invention is limited only as defined in the following claims and equivalents thereof.

What is claimed is:

1. A resistive memory device comprising:
a buffer memory for storing input data associated with a write command; and
a memory core unit including resistive memory cells for storing the input data from the buffer memory,
wherein the buffer memory is comprised of a different type of memory cells from said resistive memory cells such that the different type of memory cells writes the input data with a faster speed than said resistive memory cells.

2. The resistive memory device of claim 1, further comprising:
a first control logic unit that generates a write address signal and a write command signal to the buffer memory in response to the write command and an address from a memory controller;
wherein the buffer memory stores the input data in response to the write command signal and the write address signal.

3. The resistive memory device of claim 2, wherein the buffer memory generates a buffer status signal to the first control logic for indicating when the input data is completely stored in the memory core unit.

4. The resistive memory device of claim 3, wherein the memory core unit is controlled to perform another command from the memory controller before the input data is completely stored in the memory core unit.

5. The resistive memory device of claim 2, further comprising:
an output buffer that receives output data from the memory core unit for a read command;
wherein the buffer memory also stores the output data from the memory core unit for the read command,
and wherein the output buffer transmits the output data from one of the buffer memory and the memory core unit according to a selection signal from the first control logic unit.

6. The resistive memory device of claim 5, wherein the memory core unit includes:
a memory cell array of the resistive memory cells;
a second control logic unit that generates a control signal for controlling writing of the input data into the memory cell array and reading of the output data from the memory cell array according to the write address signal, the write command signal, a read address signal, and a read command signal that are generated by the first control logic unit;
a write driver that writes the input data into the memory cell array in response to the control signal;
a sense amplifier that senses the output from the memory cell array in response to the control signal; and
an address decoder that generates a decoded write address signal indicating an area of the memory cell array to be storing the input data and a decoded read address signal indicating an area of the memory cell array having the output data that is read.

7. The resistive memory device of claim 1, wherein the resistive memory cells are one of PRAM (phase-change random access memory) cells or RRAM (resistive random access memory) cells, and wherein the different type of memory cells of the buffer memory is one of SRAM (static random access memory) cells or DRAM (dynamic random access memory) cells.

8. A memory system comprising:
a resistive memory device; and
a memory controller generating a write command, an address, and input data to the resistive memory device;
wherein the resistive memory device includes:
a buffer memory for storing the input data associated with the write command from the memory controller; and
a memory core unit including resistive memory cells for storing the input data from the buffer memory,
wherein the buffer memory is comprised of a different type of memory cells from said resistive memory cells such that the different type of memory cells writes the input data with a faster speed than said resistive memory cells.

9. The memory system of claim 8, wherein the resistive memory device further includes:
a first control logic unit that generates a write address signal and a write command signal to the buffer memory in response to the write command and the address from the memory controller;
wherein the buffer memory stores the input data in response to the write command signal and the write address signal.

10. The memory system of claim 9, wherein the buffer memory generates a buffer status signal to the first control logic for indicating when the input data is completely stored in the memory core unit.

11. The memory system of claim 10, wherein the memory controller controls the memory core unit to perform another command before the input data is completely stored in the memory core unit.

12. The memory system of claim 9, wherein the resistive memory device further includes:
an output buffer that receives output data from the memory core unit for a read command from the memory controller;
wherein the buffer memory also stores the output data from the memory core unit for the read command,
and wherein the output buffer transmits the output data from one of the buffer memory and the memory core unit according to a selection signal from the first control logic unit.

13. The memory system of claim 12, wherein the memory core unit includes:
a memory cell array of the resistive memory cells;
a second control logic unit that generates a control signal for controlling writing of the input data into the memory cell array and reading of the output data from the memory cell array according to the write address signal, the write command signal, a read address signal, and a read command signal that are generated by the first control logic unit;
a write driver that writes the input data into the memory cell array in response to the control signal;
a sense amplifier that senses the output from the memory cell array in response to the control signal; and
an address decoder that generates a decoded write address signal indicating an area of the memory cell array to be storing the input data and a decoded read address signal indicating an area of the memory cell array having the output data that is read.

14. The memory system of claim 8, wherein the resistive memory cells are one of PRAM (phase-change random access memory) cells or RRAM (resistive random access memory) cells, and wherein the different type of memory cells of the buffer memory is one of SRAM (static random access memory) cells or DRAM (dynamic random access memory) cells.

15. A method of transferring data in a resistive memory device comprising:
writing input data associated with a write command in a buffer memory; and
writing the input data from the buffer memory into a memory core unit including resistive memory cells,
wherein the buffer memory is comprised of a different type of memory cells from said resistive memory cells such that the different type of memory cells writes the input data with a faster speed than said resistive memory cells.

16. The method of claim 15, further comprising:
generating a write address signal and a write command signal to the buffer memory in response to the write command and an address from a memory controller;
wherein the buffer memory stores the input data in response to the write command signal and the write address signal.

17. The method of claim 16, further comprising:
generating a buffer status signal from the buffer memory for indicating when the input data is completely stored in the memory core unit.

18. The method of claim 17, further comprising:
controlling the memory core unit to perform another command from the memory controller before the input data is completely stored in the memory core unit.

19. The method of claim 16, further comprising:
transferring output data from the memory core unit to an output buffer for a read command;
storing the output data from the memory core unit for the read command in the buffer memory; and
transmitting from the output buffer the output data from one of the buffer memory and the memory core unit according to a selection signal.

20. The method of claim 15, wherein the resistive memory cells are one of PRAM (phase-change random access memory) cells or RRAM (resistive random access memory) cells, and wherein the different type of memory cells of the buffer memory is one of SRAM (static random access memory) cells or DRAM (dynamic random access memory) cells.
